(19) United States
(12) Patent Application Publication
(10) Pub. No.: US 2024/0234462 A9
(43) Pub. Date: Jul. 11, 2024

(54) IMAGE SENSORS INCLUDING MICROLENSES HAVING PLURALITY OF CURVATURES AND METHODS OF FABRICATING THE SAME

(71) Applicant: Samsung Electronics Co., Ltd., Suwon-si (KR)

(72) Inventors: Minkwan Kim, Suwon-si (KR); Inyong Park, Suwon-si (KR); Jinsun Pyo, Suwon-si (KR); Beomsuk Lee, Suwon-si (KR); Sungeun Lee, Suwon-si (KR); In Sung Joe, Suwon-si (KR)

(21) Appl. No.: 18/204,974

(22) Filed: Jun. 2, 2023

(30) Foreign Application Priority Data
Oct. 19, 2022 (KR) 10-2022-0134736

(51) Int. Cl. H01L 27/146; G02B 3/00

(52) U.S. Cl. CPC H01L 27/14627; G02B 3/0043; H01L 27/14621; H01L 27/1463; H01L 27/14634; H01L 27/14645; H01L 27/14685; G02B 1/14

(57) ABSTRACT

Image sensors and fabrication methods thereof. For example, the image sensor may include a first substrate having a first surface and a second surface that are opposite to each other, a plurality of pixels provided in the first substrate and arranged in pixel groups, each pixel group including four pixels arranged in two columns and two rows, a pixel separation structure in the first substrate and including a pixel group separation part that separates each pixel group from adjacent pixel groups and a pixel separation part that separates the pixels in each pixel group from each other, and a plurality of microlenses on the first surface and respectively overlapping the plurality of pixel groups. Each of the microlenses includes a central part that has a first curvature and an edge part that has a second curvature. The first curvature is less than the second curvature.

### CROSS-REFERENCE TO RELATED APPLICATION

This U.S. nonprovisional application claims priority under 35 U.S.C § 119 to Korean Patent Application No. 10-2022-0134736 filed on Oct. 19, 2022, in the Korean Intellectual Property Office, and the entire contents of the above-identified application are hereby incorporated by reference.

### BACKGROUND

The present inventive concepts relate to image sensors and methods of fabricating the same, and more particularly, to an image sensor including a microlens having a plurality of curvatures and a method of fabricating the same.

An image sensor is a semiconductor device configured to transform optical images into electrical signals. The image sensor may be classified into a charge coupled device (CCD) type and a complementary metal oxide semiconductor (CMOS) type. The CIS (CMOS image sensor) is a short for the CMOS type image sensor. The CIS may include a plurality of two-dimensionally arranged pixels. Each of the pixels includes a photodiode (PD). The photodiode serves to transform an incident light into an electrical signal.

### SUMMARY

Some embodiments of the present inventive concepts provide image sensors capable of achieving clear or relatively clearer images.

Some embodiments of the present inventive concepts provide a method of fabricating the image sensor.

The object of the present inventive concepts is not limited to the mentioned above, and other objects which have not been mentioned above will be understood to those skilled in the art from the following description.

According to some embodiments of the present inventive concepts, an image sensor may comprise: a first substrate having a first surface and a second surface that are opposite to each other; a plurality of pixels provided in the first substrate and arranged in a plurality pixel groups, wherein each of the pixel groups includes four pixels arranged in two columns and two rows; a pixel separation structure provided in the first substrate, wherein the pixel separation structure includes a pixel group separation part that separates each pixel group from adjacent pixel groups and a pixel separation part that separates the pixels in each pixel group from each other; and a plurality of microlenses on the first surface, wherein the plurality of microlenses respectively overlap the plurality of pixel groups. Each of the microlenses may include a central part that has a first curvature and an edge part that has a second curvature. The first curvature may be less than the second curvature.

According to some embodiments of the present inventive concepts, an image sensor may comprise: a first substrate having a first surface and a second surface that are opposite to each other; a plurality of pixels provided in the first substrate and arranged in pixel groups, each of the pixel groups including pixels arranged in m columns and n rows, where at least one of m and n is a natural number equal to or greater than 2; a pixel separation structure provided in the first substrate, wherein the pixel separation structure includes a pixel group separation part that separates each pixel groups from adjacent pixel groups and a pixel separation part that separates the pixels in each pixel group from each other; and a plurality of microlenses on the first surface, wherein the plurality of microlenses respectively overlap the plurality of pixel groups. Each of the microlenses may include a central part that has a first curvature radius and an edge part that has a second curvature radius. The first curvature radius may be greater than the second curvature radius.

According to some embodiments of the present inventive concepts, an image sensor may comprise: a first substrate having a first surface and a second surface that are opposite to each other; a plurality of pixels provided in the first substrate and arranged in pixel groups, each of the pixel groups including four pixels arranged in two columns and two rows; a photoelectric conversion element in the first substrate in each of the pixels; a transfer gate on the second surface for each of the pixels; a pixel separation structure on the first surface, wherein the pixel separation structure includes a polysilicon pattern and a dielectric pattern that surrounds a lateral surface of the polysilicon pattern, the pixel separation structure including a pixel group separation part that separates each pixel group from adjacent pixel groups and a pixel separation part that separates the pixels in each pixel group from each other; a plurality of color filters on the first surface, the plurality of color filters respectively overlapping the plurality of pixel groups; and a plurality of microlenses correspondingly on the color filters. Each of the microlenses may include a central part that has a first curvature and an edge part that has a second curvature. The central part may have a first focal distance. The edge part may have a second focal distance less than the first focal distance. A second focus of the edge part may be at a point about −500 nm to about +500 nm from the first surface toward the second surface.

According to some embodiments of the present inventive concepts, a method of fabricating an image sensor may comprise: providing a first substrate having a first surface and a second surface that are opposite to each other; forming a pixel separation structure in the first substrate that separates a plurality of pixels from each other and a plurality of pixel groups from each other, wherein each of the pixel groups includes pixels from the plurality of pixels that are arranged in m columns and n rows, where at least one of m and n is a natural number equal to or greater than 2; forming a preliminary lens layer on the first surface; forming a first photoresist pattern on the preliminary lens layer; and performing a blanket etch-back process to transfer a shape of the first photoresist pattern to the preliminary lens layer to form a plurality of microlenses that respectively overlap the plurality of pixel groups. Each of the microlenses may be formed to have a central portion having a first curvature and an edge part having a second curvature less than the first curvature.

According to some embodiments of the present inventive concepts, a method of fabricating an image sensor may comprise: providing a first substrate having a first surface and a second surface that are opposite to each other; forming, in the first substrate, a pixel separation structure that separates a plurality of pixels from each other and a plurality of pixel groups from each other, wherein each of the pixel groups includes pixels from the plurality of pixels that are arranged in m columns and n rows, where at least one of m n is a natural number equal to or greater than 2; forming a preliminary lens layer on the first surface; forming a first photoresist pattern on the preliminary lens layer; reflowing the first photoresist pattern to from a first reflowed pattern; performing a blanket etch-back process to transfer a shape of the first reflowed pattern to the preliminary lens layer to form a plurality of preliminary microlenses; forming a second photoresist pattern that covers a central part of each of the preliminary microlenses and to expose an edge part of each of the preliminary microlenses; etching the edge part by using the second photoresist pattern as an etching mask; and removing the second photoresist pattern.

### BRIEF DESCRIPTION OF THE DRAWINGS

FIG. 1 illustrates a block diagram showing an image sensor according to some embodiments of the present inventive concepts.

FIG. 2 illustrates a circuit diagram showing an active pixel sensor array of an image sensor according to some embodiments of the present inventive concepts.

FIGS. 3A and 3B illustrate plan views showing an image sensor according to some embodiments of the present inventive concepts.

FIGS. 4A and 4B illustrate cross-sectional views taken along line A-A′ of FIGS. 3A and 3B.

FIG. 5 illustrates a plan view showing a light distribution of an image sensor according to some embodiments of the present inventive concepts.

FIG. 6A illustrates a cross-sectional view showing an image sensor according to some embodiments of the present inventive concepts.

FIG. 6B illustrates an enlarged view showing section P1 of FIG. 6A.

FIG. 7 illustrates a cross-sectional view showing an image sensor according to some embodiments of the present inventive concepts.

FIG. 8 illustrates a plan view showing an image sensor according to some embodiments of the present inventive concepts.

FIG. 9 illustrates a cross-sectional view taken along line A-A′ of FIG. 8.

FIG. 10 illustrates a cross-sectional view showing a method of fabricating an image sensor having the cross-section of FIG. 4A.

FIGS. 11A to 11D illustrate cross-sectional view showing a method of fabricating an image sensor having the cross-section of FIG. 4A.

FIGS. 12A and 12B illustrate cross-sectional views showing a method of fabricating an image sensor having the cross-section of FIG. 4A.

FIG. 13A illustrates a plan view showing an image sensor according to some embodiments of the present inventive concepts.

FIG. 13B illustrates a cross-sectional view taken along line B-B′ of FIG. 13A.

FIG. 14 illustrates a cross-sectional view showing an image sensor according to some embodiments of the present inventive concepts.

FIG. 15 illustrates a cross-sectional view showing an image sensor according to some embodiments of the present inventive concepts.

### DETAILED DESCRIPTION

Some embodiments of the present inventive concepts will now be described in detail with reference to the accompanying drawings, which aid in providing clear explanations of the present inventive concepts.

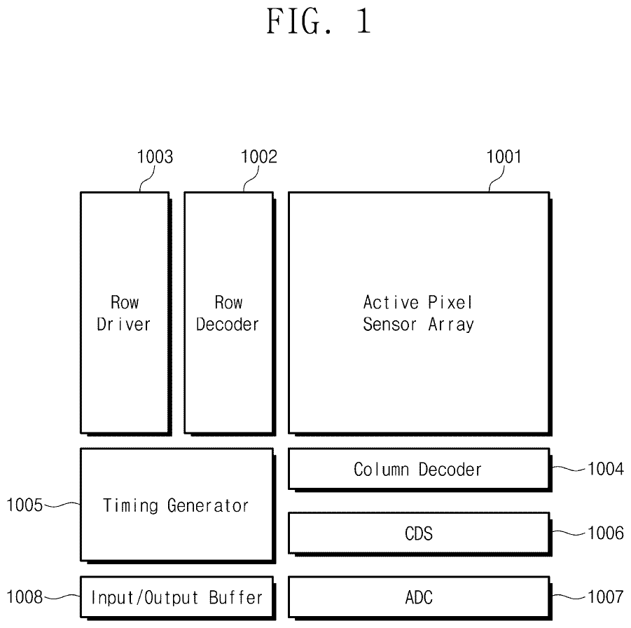

FIG. 1 illustrates a block diagram showing an image sensor according to some embodiments of the present inventive concepts.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of two-dimensionally arranged unit pixels, each of which may be configured to convert optical signals into electrical signals. The active pixel sensor array 1001 may be driven by a plurality of driving signals, such as a pixel selection signal, a reset signal, and a charge transfer signal, from the row driver 1003. The correlated double sampler 1006 may be provided with the converted electrical signals.

The row driver 1003 may provide the active pixel sensor array 1001 with several driving signals (e.g., the pixel selection signal, the reset signal, and the charge transfer signal) for driving several unit pixels in accordance with a decoded result obtained from the row decoder 1002. When the unit pixels are arranged in a matrix shape, the driving signals may be provided for respective rows.

The timing generator 1005 may provide timing and control signals to the row decoder 1002 and the column decoder 1004.

The correlated double sampler 1006 may receive the electrical signals generated from the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise and signal levels.

The analog-to-digital converter 1007 may convert analog signals, which correspond to the difference level received from the correlated double sampler 1006, into digital signals, and then may output the converted digital signals.

The input/output buffer 1008 may latch the digital signals and then may sequentially output the latched digital signals to an image signal processing unit (not shown) in response to the decoded result obtained from the column decoder 1004.

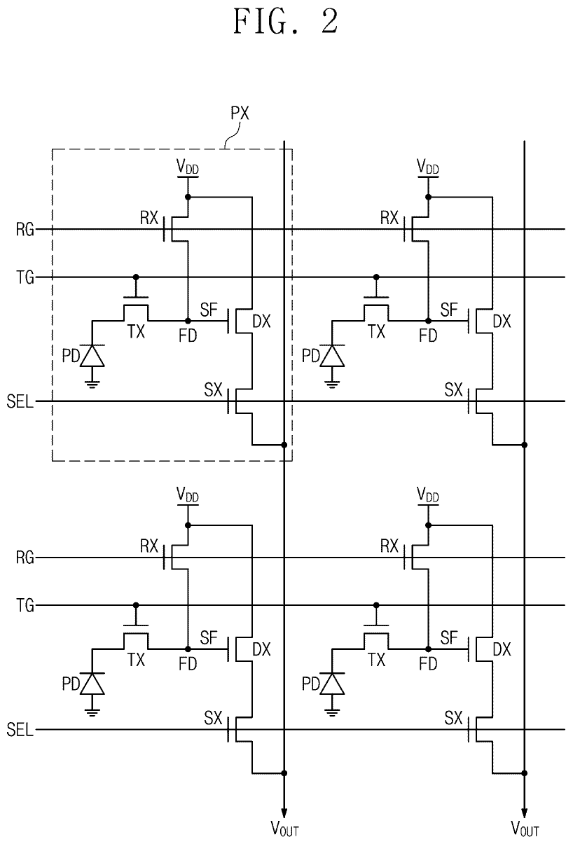

FIG. 2 illustrates a circuit diagram showing an active pixel sensor array of an image sensor according to some embodiments of the present inventive concepts.

Referring to FIGS. 1 and 2, the sensor array 1001 may include a plurality of unit pixels PX, and the plurality of unit pixels PX may be arranged in a matrix shape. Each of the unit pixels PX may include a transfer transistor TX. Each of the unit pixels PX may further include logic transistors RX, SX, and DX. The logic transistors RX, SX, and DX may include a reset transistor RX, a selection transistor SX, and a source follower transistor DX. The transfer transistor TX may include a transfer gate TG. Each of the unit pixels PX may further include a photoelectric conversion element PD and a floating diffusion region FD. In some embodiments, the logic transistors RX, SX, and DX may be shared by a plurality of unit pixels PX.

The photoelectric conversion element PD may create and accumulate photo-charges in proportion to an amount of externally incident light. The photoelectric conversion element PD may include a photodiode, phototransistor, a photogate, a pinned photodiode, or a combination thereof. The transfer transistor TX may transfer charges generated in the photoelectric conversion element PD into the floating diffusion region FD. The floating diffusion region FD may accumulate and store charges that are generated and transferred from the photoelectric conversion element PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage VDD. When the reset transistor RX is turned on, the floating diffusion region FD may be supplied with the power voltage VDD connected to the source electrode of the reset transistor RX. Accordingly, when the reset transistor RX is turned on, the charges accumulated in the floating diffusion region FD may be exhausted and thus the floating diffusion region FD may be reset.

The source follower transistor DX including a source follower gate SF may serve as a source follower buffer amplifier. The source follower transistor DX may amplify a variation in electrical potential of the floating diffusion region FD and may output the amplified electrical potential to an output line VOUT.

The selection transistor SX including a selection gate SEL may select each row of the unit pixel P to be readout. When the selection transistor SX is turned on, the power voltage VDD may be applied to a drain electrode of the source follower transistor DX.

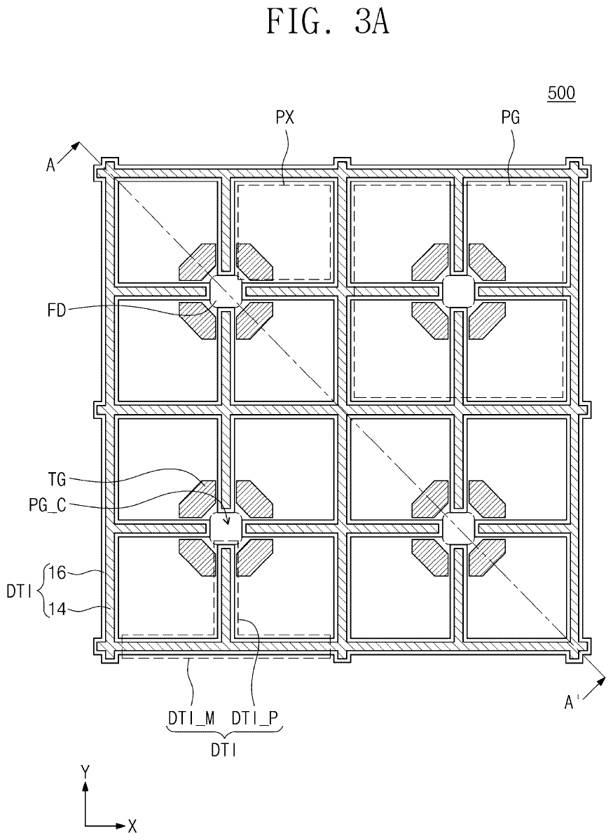

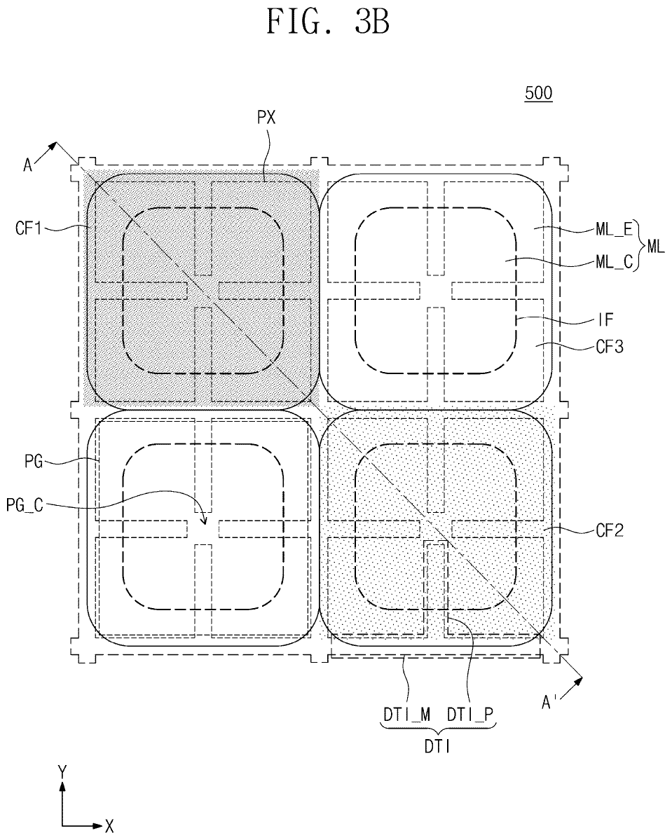

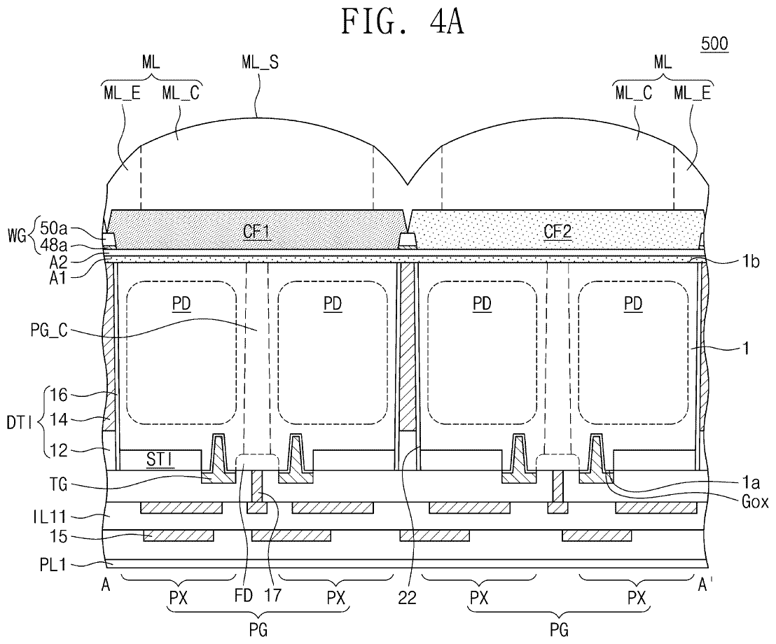

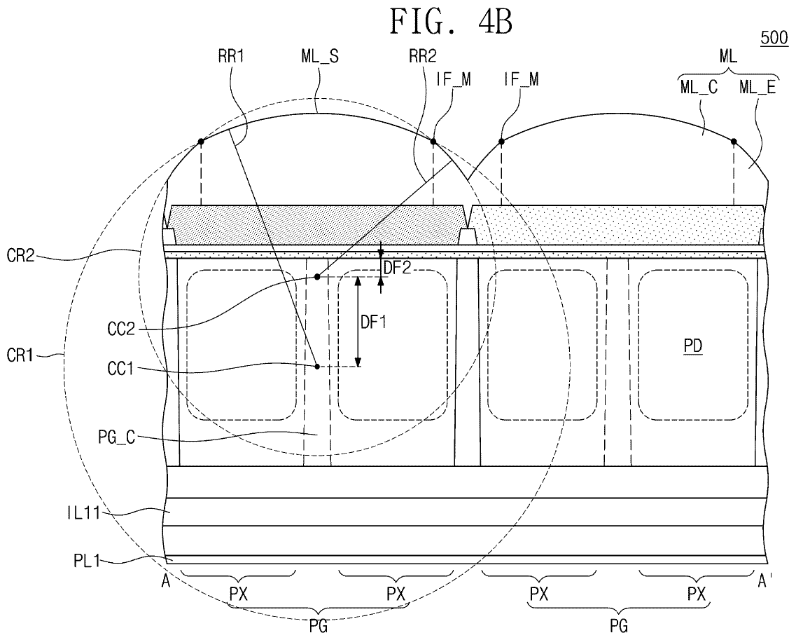

FIGS. 3A and 3B illustrate plan views showing an image sensor according to some embodiments of the present inventive concepts. FIGS. 4A and 4B illustrate cross-sectional views taken along line A-A′ of FIGS. 3A and 3B.

Referring to FIGS. 3A, 3B, 4A, and 4B, an image sensor 500 according to some embodiments may include a first substrate 1. The first substrate 1 may be, for example, a monocrystalline silicon wafer, a silicon epitaxial layer substrate, or a silicon-on-insulator (SOI) substrate. The first substrate 1 may be doped with impurities having a first conductivity type. For example, the first conductivity type may be a p-type. The first substrate 1 may have a front surface 1a and a rear surface 1b that are opposite to each other. In this description, the front surface 1a may be called a first surface, and the rear surface 1b may be called a second surface.

The first substrate 1 may be provided therein with a pixel separation structure DTI that separates a plurality of pixels PX from each other. The pixels PX may be two-dimensionally arranged along a first direction X and a second direction Y. A single pixel group PG may be constituted by four pixels PX arranged in two columns and two rows adjacent to each other. The present inventive concepts, however, are not limited thereto, and one pixel group PG may have pixels PX that are arranged in m columns and n rows. At least one selected from m and n may be a natural number equal to or greater than 2.

The pixel separation structure DTI may include a pixel group separation part DTI_M and a pixel separation part DTI_P. The pixel group separation part DTI_M may be interposed between neighboring pixel groups PG and may separate neighboring pixel groups PG. The pixel separation part DTI_P may separate the pixels PX from each other in one pixel group PG. When viewed in plan (and as seen in FIG. 3A), the pixel separation part DTI_P may protrude from a lateral surface of the pixel group separation part DTI_M toward a center PG_C of the pixel group PG. As shown in FIGS. 3A and 3B, the pixel separation part DTI_P may be absent on the center PG_C of the pixel group PG. Thus, the pixel separation parts DTI_P may be spaced apart from each other in one pixel group PG. Stated differently, the pixel separation parts DTI_P of a pixel group PG may not contact each other at a center PG_C of the pixel group PG.

The pixel separation structure DTI may be positioned in a deep trench 22 formed from the front surface 1a and toward the rear surface 1b of the first substrate 1. The pixel separation structures DTI may include a buried dielectric pattern 12, a separation dielectric pattern 16, and a separation conductive pattern 14. The buried dielectric pattern 12 may be interposed between the separation conductive pattern 14 and a first interlayer dielectric layer IL11 which will be discussed below. The separation dielectric pattern 16 may be interposed between the separation conductive pattern 14 and the first substrate 1 and between the buried dielectric pattern 12 and the first substrate 1.

The buried dielectric pattern 12 and the separation dielectric pattern 16 may be formed of a dielectric material whose refractive index is different from that of the first substrate 1. The buried dielectric pattern 12 and the separation dielectric pattern 16 may include, for example, silicon oxide. The separation conductive pattern 14 may be spaced apart from the first substrate 1 (for example, by the separation dielectric pattern 16). The separation conductive pattern 14 may include an impurity-doped polysilicon layer or an impurity-doped silicon-germanium layer. For example, one of boron, phosphorus, and arsenic may be adopted as impurities doped into the polysilicon layer or the silicon-germanium layer. Alternatively, the separation conductive pattern 14 may include a metal layer.

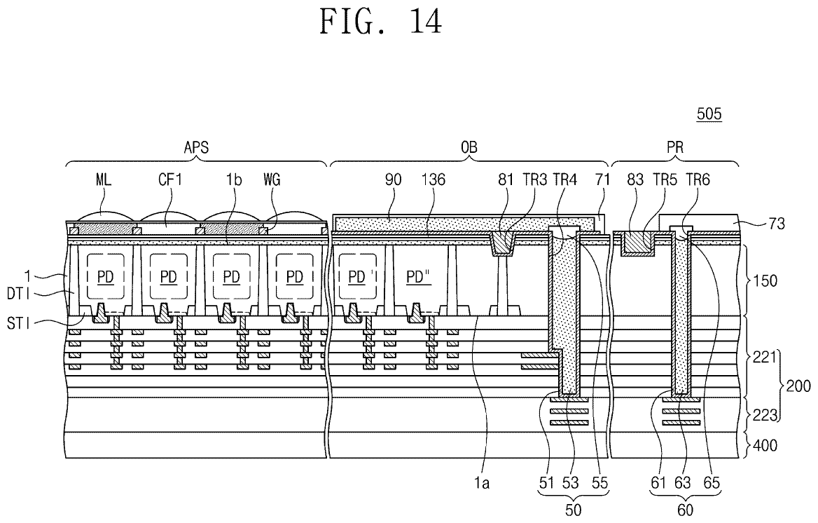

The separation conductive pattern 14 may be provided with a negative bias voltage through a connection contact 81 of FIG. 14. The separation conductive pattern 14 may serve as a common bias line. Therefore, holes possibly present on a surface of the first substrate 1 in contact with the pixel separation structure DTI may be trapped to improve dark current properties.

The pixel separation structure DTI may have a width that decreases in a direction from the front surface 1a toward the rear surface 1b of the first substrate 1. In this description, the language “width” may be replaced with the language “thickness”.

The pixels PX may include corresponding photoelectric conversion elements PD provided in the first substrate 1. The photoelectric conversion elements PD may be doped with impurities having a second conductivity type opposite to the first conductivity type. The second conductivity type may be, for example, an n-type. The n-type impurities doped in the photoelectric conversion element PD and the p-type impurities doped in the first substrate 1 therearound may constitute a PN junction to provide a photodiode.

The first substrate 1 may have therein device separation parts STI adjacent to the front surface 1a. The pixel separation structure DTI may penetrate or extend through the device separation parts STI. On each pixel PX, the device separation parts STI may define active sections adjacent to the front surface 1a. The active sections may be prepared for the transistors TX, RX, DX, and SX of FIG. 2.

Referring to FIG. 3A, on each pixel PX, a transfer gate TG may be on the front surface 1a of the first substrate 1. On the pixels PX included in one pixel group PG, the transfer gates TG may be adjacent to the center PG_C of one pixel group PG. A portion of the transfer gate TG may extend into the first substrate 1. The transfer gate TG may have a vertical type. Alternatively, the transfer gate TG may have a planar type that does not extend into the first substrate 1. As seen in FIG. 4A, a gate dielectric layer Gox may be interposed between the transfer gate TG and the first substrate 1. The first substrate 1 may be provided with a floating diffusion region FD adjacent to the front surface 1a on the center PG_C of one pixel group PG. The floating diffusion region FD may be doped with impurities having, for example, the second conductivity type. Four transfer gates TG may be adjacent to the floating diffusion region FD. The four pixels PX included in one pixel group PG may share one floating diffusion region FD.

The image sensor 500 may be a backside illumination image sensor. Light may be incident on the first substrate 1 through the rear surface 1b of the first substrate 1. Electron-hole pairs may be created from the incident light at the PN junction. These created electrons may move toward the photoelectric conversion element PD. When a voltage is applied to the transfer gate TG, the electrons may move toward the floating diffusion region FD.

Although not shown, on the pixels PX, the front surface 1a may be provided thereon with a reset transistor RX, a selection transistor SX, and a source follower transistor DX.

First interlayer dielectric layers IL11 may be on the front surface 1a. The first interlayer dielectric layers IL11 may be formed of a multiple layer including at least one selected from a silicon oxide layer, a silicon nitride layer, a silicon oxynitride layer, and a porous low-k dielectric layer. The first interlayer dielectric layers IL11 may be provided with first wiring lines 15 therebetween or therein. The floating diffusion region FD may be connected through a first contact plug 17 to the first wiring lines 15. The first contact plug 17 may penetrate or extend through an uppermost one of the first interlayer dielectric layers IL11 that is most adjacent to the front surface 1a. A lowermost one of the first interlayer dielectric layers IL11 may be covered with a passivation layer PL1. The passivation layer PL1 may include a single-layered or multi-layered structure of at least one selected from silicon oxide, SiCN, and SiN.

The rear surface 1b of the first substrate 1 may be sequentially covered with a fixed charge layer A1 and an antireflection layer A2. The fixed charge layer A1 may be in contact with the rear surface 1b. The fixed charge layer A1 may have a negative fixed charge. The fixed charge layer A1 may be formed of one of metal oxide and metal fluoride that include at least one metal selected from hafnium (Hf), zirconium (Zr), aluminum (Al), tantalum (Ta), titanium (Ti), yttrium (Y), and lanthanides. For example, the fixed charge layer A1 may be a hafnium oxide layer or an aluminum oxide layer. Hole accumulation may occur around the fixed charge layer A1. Therefore, dark current and white spot may be effectively reduced.

The antireflection layer A2 may have a single-layered or multi-layered structure of at least one selected from titanium oxide, silicon nitride, silicon oxide, and hafnium oxide.

A grid pattern WG may be provided on the antireflection layer A2. The grid pattern WG may include a light-shield grid 48a and a low-refractive grid 50a that are sequentially stacked. The grid pattern WG may overlap the pixel separation structure DTI. The light-shield grid 48a may include, for example, at least one selected from titanium, titanium nitride, and tungsten. The low-refractive grid 50a may include a material whose refractive index is less than that of color filters CF1, CF2, and CF3, which will be discussed in greater detail below. For example, the low-refractive grid 50a may have a refractive index of equal to or less than about 1.3. The light-shield grid 48a may have sidewalls aligned with those of the low-refractive grid 50a.

Color filters CF1, CF2, and CF3 may be between the grid patterns WG. Each of the color filters CF1, CF2, and CF3 may have one of blue, green, and red colors. Alternatively, the color filters CF1, CF2, and CF3 may include different colors such as cyan, magenta, and yellow. The color filters CF1, CF2, and CF3 may be arranged in a Bayer pattern. Alternatively, the color filters CF1, CF2, and CF3 may be arranged in one of 2x2 Tetra, 3x3 Nona, and 4x4 Hexadeca patterns. One of the color filters CF1, CF2, and CF3 may cover one pixel group PG.

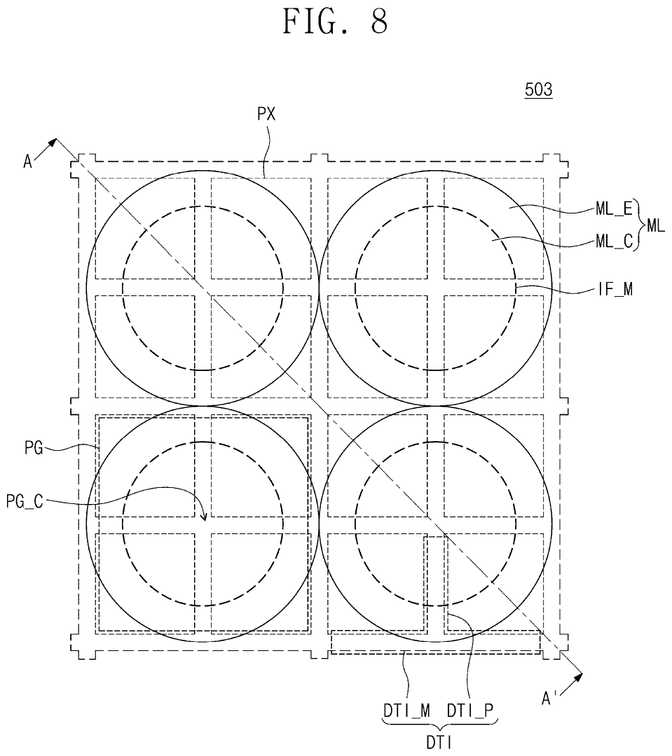

Microlenses ML may be provided on the color filters CF1, CF2, and CF3. One microlens ML may be positioned on one pixel group PG. The microlenses ML may each have a tetragonal shape having rounded corners when viewed in plan as shown in FIG. 3B. Alternatively, the microlenses ML may each have a circular shape when viewed in plan as shown in FIG. 8.

Each of the microlenses ML may have a lens central part ML_C and a lens edge part ML_E. The edge parts ML_E of the microlenses ML may be connected to each other. The lens central part ML_C of the microlens ML may overlap the center PG_C of the pixel group PG. The microlens ML may have a plurality of curvatures at a top surface ML_S thereof.

Referring to FIG. 4B, the lens central part ML_C and the lens edge part ML_E of the microlens ML may have respective top surfaces, and slopes of tangent lines on the top surfaces may be gradually changed depending on position. The lens central part ML_C of the microlens ML may have a first curvature, and the lens edge part ML_E of the microlens ML may have a second curvature. The first curvature may be less than the second curvature. For example, the first curvature may be equal to or less than about ⅔ times the second curvature. Alternatively, the second curvature may be equal to or greater than about 1.5 times the first curvature.

The top surface of the lens central part ML_C of the microlens ML may correspond to an arc that is a portion of circumference of a first imaginary circle CR1 having a first radius RR1 and a first center CC1. The top surface of the lens edge part ML_E of the microlens ML may correspond to an arc that is a portion of circumference of a second imaginary circle CR2 having a second radius RR2 and a second center CC2.

The first radius RR1 may be called “a first focal distance” or “a first curvature radius” of the lens central part ML_C of the microlens ML. The second radius RR2 may be called “a second focal distance” or “a second curvature radius” of the lens edge part ML_E of the microlens ML. The second curvature radius RR2 may be less than the first curvature radius RR1. For example, the first curvature radius RR1 may be equal to or greater than about 1.3 times or about 1.5 times the second curvature radius RR2. The first curvature radius RR1 may be equal to or less than about one million times the second curvature radius RR2. On the top surface ML_S of the microlens ML, a lens corner IF_M may be positioned between the lens central part ML_C and the lens edge part ML_E. The lens corner IF_M may be defined to refer to a point at which a curvature at the top surface ML_S of the microlens ML is discontinuously changed from the first curvature to the second curvature. According to some embodiments, the lens corner IF_M may be a point at which a curvature at the top surface ML_S of the microlens ML is discontinuously increased to about 1.5 times.

The first center CC1 may be called “a first focal position” of the lens central part ML_C of the microlens ML. The second center CC2 may be called “a second focal position” of the lens edge part ML_E of the microlens ML. The first focal position CC1 and the second focal position CC2 may be located on the center PG_C of the pixel group PG.

The first focal position CC1 of the lens central part ML_C of the microlens ML may have a first distance DF1 from the rear surface 1b of the first substrate 1. The second focal position CC2 of the lens edge part ML_E of the microlens ML may have a second distance DF2 from the rear surface 1b of the first substrate 1. The first distance DF1 may be greater than the second distance DF2. The second distance DF2 may be, for example, about −500 nm to about +500 nm from the rear surface 1b to the front surface 1a.

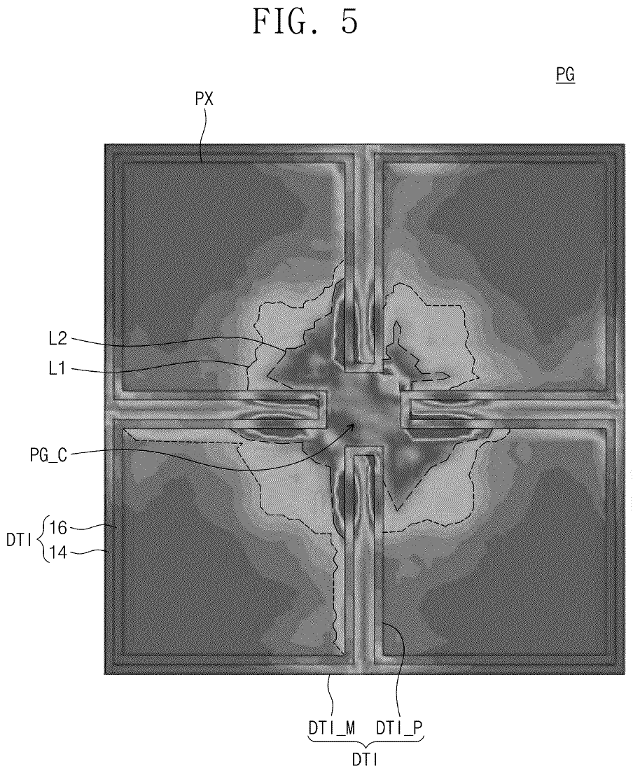

FIG. 5 illustrates a plan view showing a light distribution of an image sensor according to some embodiments of the present inventive concepts. For example, FIG. 5 shows a light distribution at the rear surface 1b, when viewed in plan, when light is incident on one pixel group PG of the image sensor discussed with reference to FIGS. 3A to 4B.

Referring to FIGS. 4B and 5, a first light L1 incident through the lens central part ML_C of the microlens ML may be mainly irradiated into the pixels PX of the pixel group PG, thereby providing a contribution to image sensing and causing an improvement in light sensitivity. In contrast, a second light L2 incident through the lens edge part ML_E of the microlens ML may be mainly irradiated close to the center PG_C of the pixel group PG. The first light L1 may be defocused, and there may be a reduction in intensity of light irradiated to the separation conductive pattern 14. However, the second light L2 may be focused, and there may be an increase in autofocus contrast (AF-C).

As the separation conductive pattern 14 formed of polysilicon has strong light absorption properties, an increase in amount (intensity) of light irradiated to the separation conductive pattern 14 may cause an increase in light loss and a reduction in light sensitivity. When the microlens ML is formed to have one curvature to create one focal position, there may be an increase in amount of light incident on the separation conductive pattern 14, which may result in a reduction in light sensitivity and autofocus contrast (AF-C).

However, in the present inventive concepts, because each of the microlenses ML has a structure including a plurality of curvatures, an amount of light incident on the separation conductive pattern 14 may be reduced to improve light sensitivity may be improved and simultaneously to increase autofocus contrast (AF-C). Accordingly, it may be possible to provide an autofocus image sensor producing clear images.

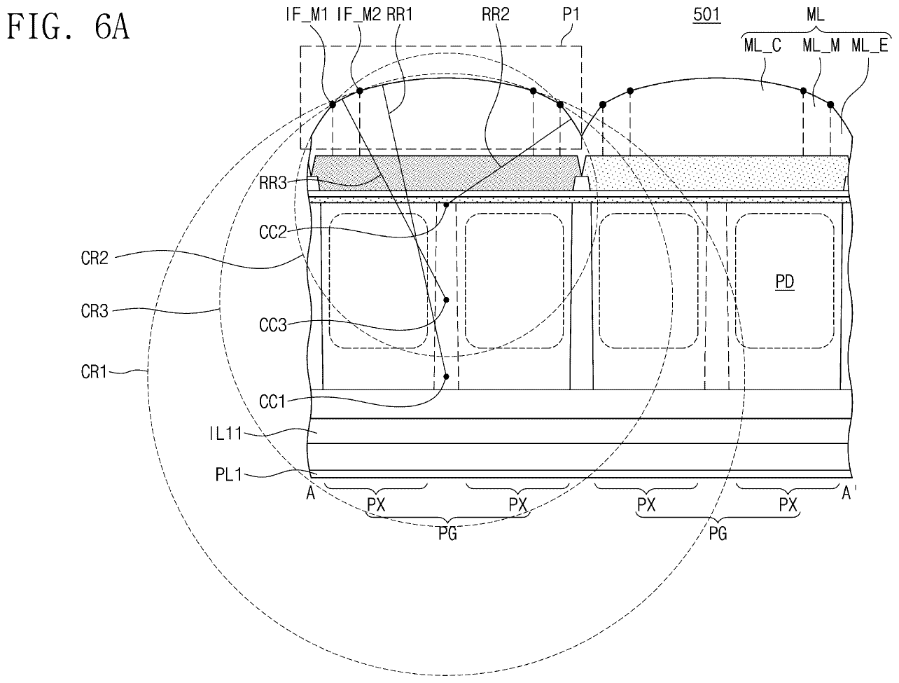

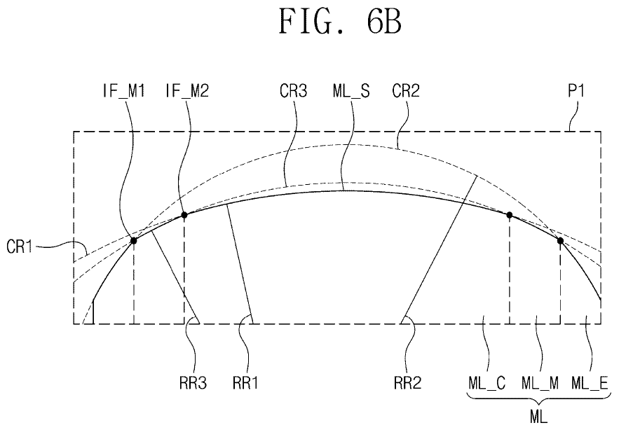

FIG. 6A illustrates a cross-sectional view showing an image sensor according to some embodiments of the present inventive concepts. FIG. 6B illustrates an enlarged view showing section P1 of FIG. 6A.

Referring to FIGS. 6A and 6B, an image sensor 501 according to the present embodiment may be configured such that the microlens ML further includes a lens connection part ML_M positioned between the lens central part ML_C and the lens edge part ML_E. The lens connection part ML_M may have a third curvature. The third curvature of the lens connection part ML_M may be greater than the first curvature of the lens central part ML_C and less than the second curvature of the lens edge part ML_E.A top surface of the lens connection part ML_M may correspond to an arc that is a portion of circumference of a third imaginary circle CR3 having a third radius RR3 and a third center CC3. The third radius RR3 may be called “a third focal distance” or “a third curvature radius” of the lens connection part ML_M of the microlens ML. The third curvature radius RR3 of the lens connection part ML_M of the microlens ML may be less than the first curvature radius RR1 of the lens central part ML_C of the microlens ML and greater than the second curvature radius RR2 of the lens edge part ML_E of the microlens ML. On the top surface ML_S of the microlens ML, a first lens corner IF_M1 may be positioned between the lens connection part ML_M and the lens edge part ML_E, and a second lens corner IF_M2 may be positioned between the lens connection part ML_M and the lens central part ML_C. The third center CC3 may be called “a third focal position” of the lens connection part ML_M of the microlens ML. The third focal position CC3 may be located on the center PG_C of the pixel group PG. The third focal position CC3 may be located between the first focal position CC1 and the second focal position CC2. The first lens corner IF_M1 and the second lens corner IF_M2 may each be defined to refer to a point at which a curvature at the top surface ML_S of the microlens ML is discontinuously changed to the first to third curvatures. Other configurations and/or components of the embodiments according to FIGS. 6A and 6B may be identical or similar to those discussed with reference to FIGS. 3A to 4B.

In this description, the microlens ML is explained to have two or three curvatures, but the present inventive concepts are not limited thereto and the microlens ML may have four or more curvatures.

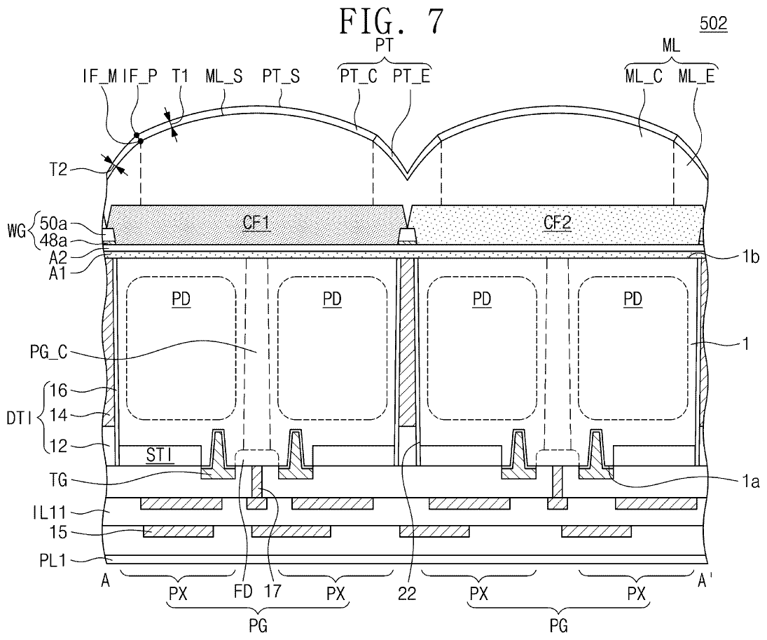

FIG. 7 illustrates a cross-sectional view showing an image sensor according to some embodiments of the present inventive concepts.

Referring to FIG. 7, an image sensor 502 according to some embodiments may further include a protection layer PT that covers the microlens ML. The protection layer PT may have a single-layered or multi-layered structure of at least one selected from, for example, silicon oxide, silicon nitride, silicon oxynitride, silicon carbide, silicon carbon oxide, silicon carbonitride, silicon carbon oxide nitride, aluminum oxide, zinc oxide, and hafnium oxide. The protection layer PT may have a central protection part PT_C on the lens central part ML_C of the microlens ML, and may also have an edge protection part PT_E on the lens edge part ML_E of the microlens ML. The central protection part PT_C may have a curvature less than that of the edge protection part PT_E. A protection-layer corner IF_P may be positioned between the central protection part PT_C and the edge protection part PT_E. The central protection part PT_C may have a first thickness T1 less than a second thickness T2 of the edge protection part PT_E. The second thickness T2 may decrease in a direction toward an edge of the pixel group PG. Other configurations and/or components of the embodiments according to FIG. 7 may be identical or similar to those discussed with reference to FIGS. 3A to 4B. In some embodiments, the protection layer PT described with reference to FIG. 7 may be provided with a microlens ML having three or more curvatures and/or including one or more lens connection parts ML_M positioned between the lens central part ML_C and the lens edge part ML_E, as described with reference to FIGS. 6A and 6B.

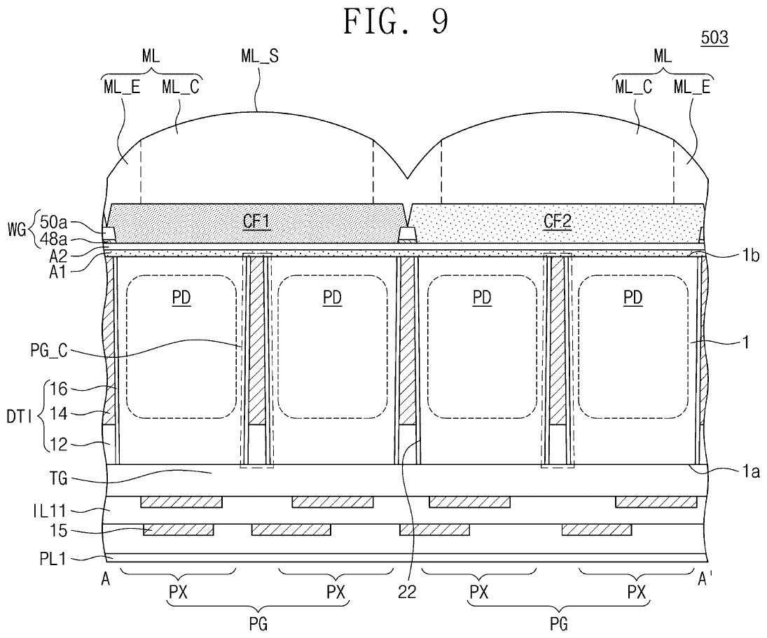

FIG. 8 illustrates a plan view showing an image sensor according to some embodiments of the present inventive concepts. FIG. 9 illustrates a cross-sectional view taken along line A-A′ of FIG. 8.

Referring to FIGS. 8 and 9, in an image sensor 503 according to the present embodiment may be configured such that the pixel separation parts DTI_P are connected to each other on the center PG_C of the pixel group PG. For example, the pixel separation part DTI_P may be on the center PG_C of the pixel group PG. The separation conductive pattern 14 of the pixel separation part DTI_P may be present on the center PG_C of the pixel group PG. Additionally, the microlenses ML may each have a circular shape when viewed in plan. Other configurations and/or components of the embodiments to FIGS. 8 and 9 may be identical or similar to those discussed with reference to FIGS. 3A to 4B. In some embodiments, one or more of the aspects of FIGS. 8 and 9 may be combined with the protection layer PT described with reference to FIG. 7, and/or may be provided with a microlens ML having three or more curvatures and/or including one or more lens connection parts ML_M positioned between the lens central part ML_C and the lens edge part ML_E, as described with reference to FIGS. 6A and 6B.

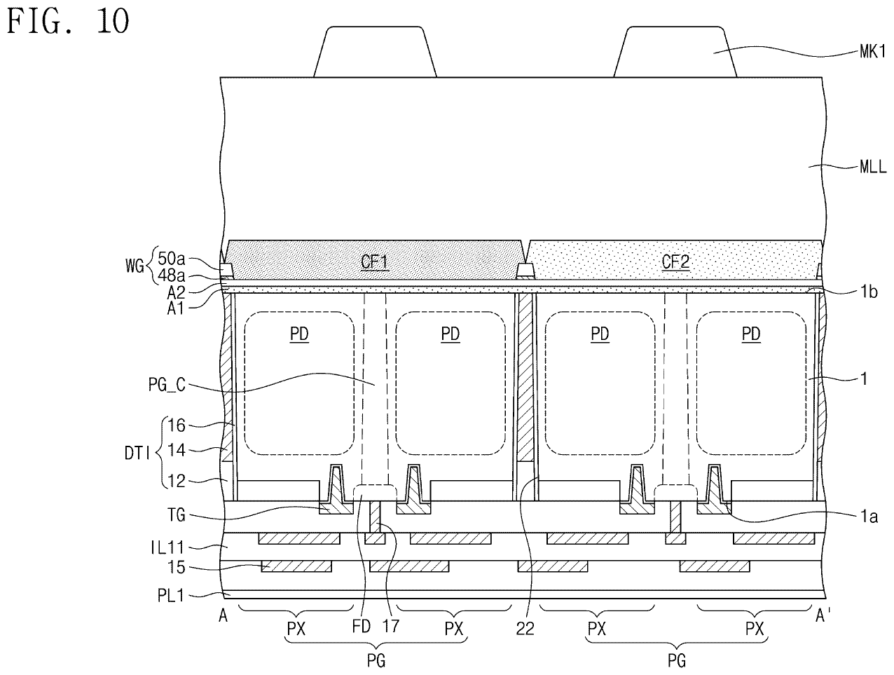

FIG. 10 illustrates a cross-sectional view showing a method of fabricating an image sensor having the cross-section of FIG. 4A.

Referring to FIG. 10, a photoelectric conversion element PD and a pixel separation structure DTI may be formed on a first substrate 1. The first substrate 1 may be provided with a transfer gate TG, a device separation part STI, first wiring lines 15, a first interlayer dielectric layer IL11, and a passivation layer PL1 that are formed on a front surface 1a of the first substrate 1. A rear surface 1b of the first substrate 1 may undergo a back-grinding process to expose a separation conductive pattern 14 of the pixel separation structure DTI. A fixed charge layer A1 and an antireflection layer A2 may be sequentially stacked on the rear surface 1b of the first substrate 1. A grid pattern WG may be formed on the antireflection layer A2. Color filters CF1 and CF2 (and, although not shown, color filter CF3) may be formed on the antireflection layer A2 between segments of the grid pattern WG. A preliminary lens layer MLL may be formed on the color filters CF1 and CF2. The preliminary lens layer MLL may be formed of a transparent photoresist material or a transparent thermosetting resin. A first mask pattern MK1 may be formed on the preliminary lens layer MLL. The first mask pattern MK1 may be a photoresist pattern formed by a photolithography process. The first mask pattern MK1 may be formed to have a rounded upper corner. The first mask pattern MK1 may have a width that increases in a downward direction.

Referring back to FIG. 4A, the preliminary lens layer MLL may be etched by performing a blanket etch-back process in a state where the first mask pattern MK1 is formed. Therefore, a profile of the first mask pattern MK1 may be transferred to the preliminary lens layer MLL to form microlenses ML shown in FIG. 4A. For example, a flat or substantially flat upper portion of the first mask pattern MK1 may be transferred to form lens central parts ML_C, each having a first curvature, of the microlenses ML, and an inclined sidewall of the first mask pattern MK1 may be transferred to form lens edge parts ML_E, each having a second curvature, of the microlenses ML. During the blanket etch-back process, the first mask pattern MK1 may all be etched and removed. Accordingly, an image sensor 500 may be fabricated as shown in FIG. 4A.

Another method may be used to fabricate the image sensor 500 of FIG. 4A.

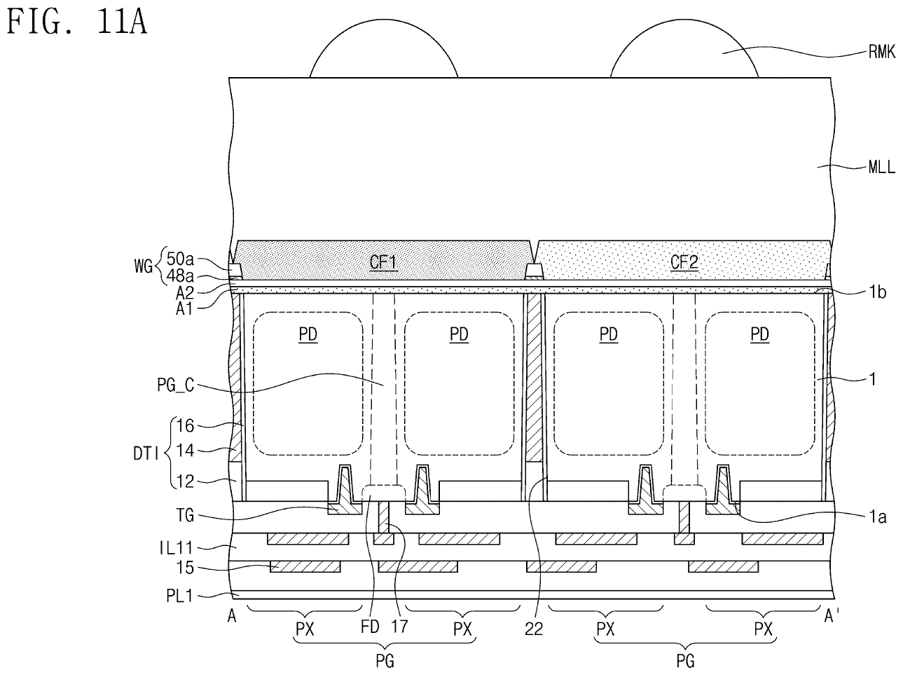

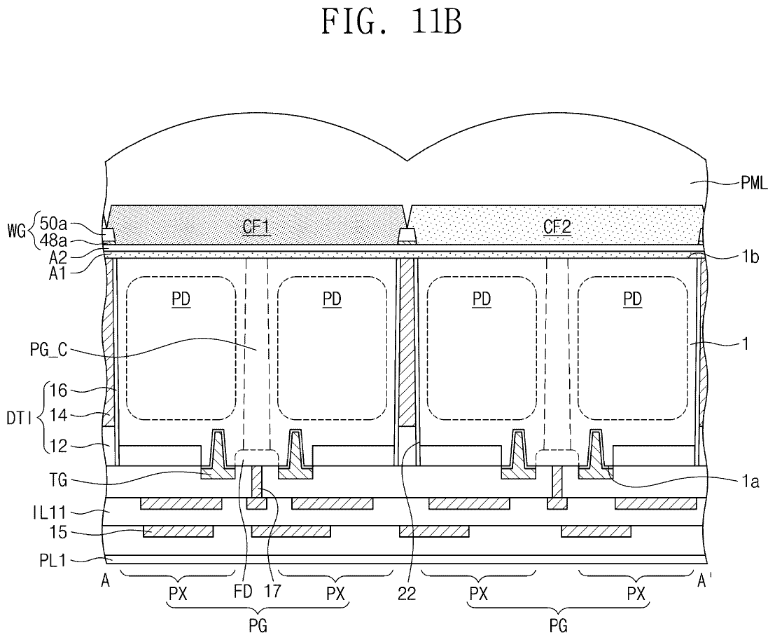

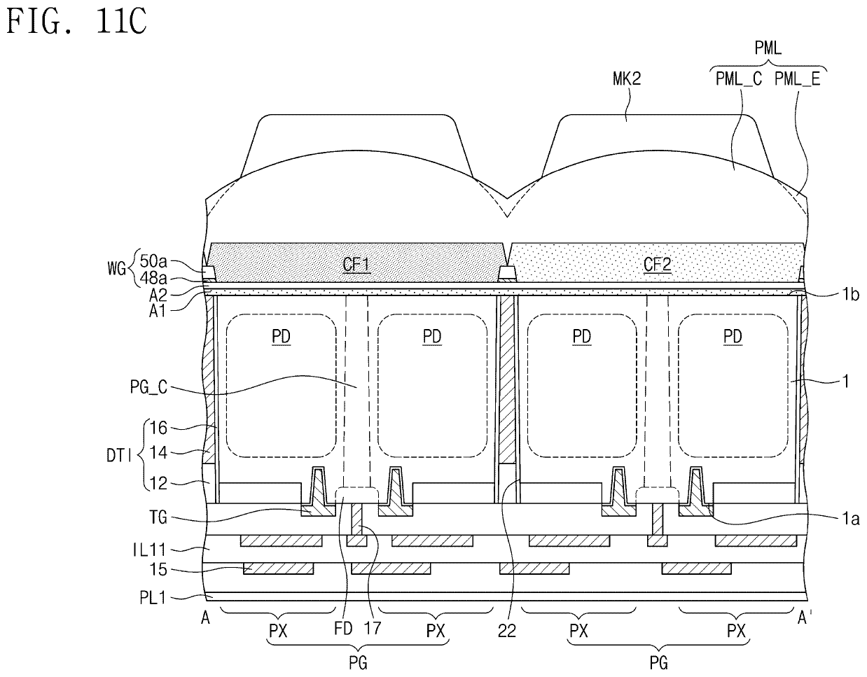

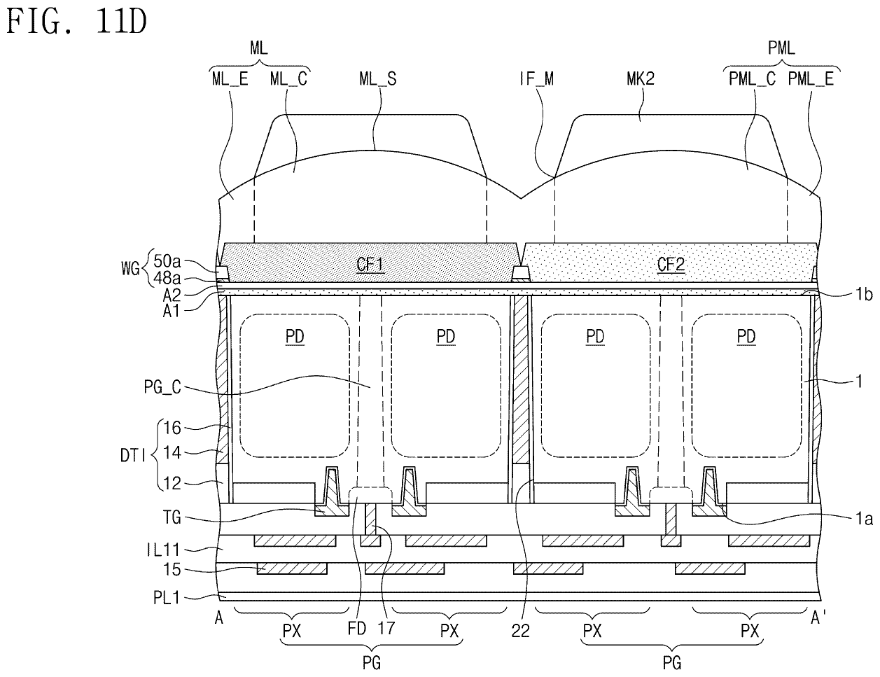

FIGS. 11A to 11D illustrate cross-sectional view showing a method of fabricating an image sensor having the cross-section of FIG. 4A.

Referring to FIG. 11A, in a fabrication method according to some embodiments, the first mask pattern MK1 may be formed rounded by performing a reflow process in the state of FIG. 4A. For example, a reflowed mask pattern MK1 may be formed.

Referring to FIG. 11B, the preliminary lens layer MLL may be etched by performing a blanket etch-back process in a state where the reflowed mask pattern MK1 is formed. Therefore, a profile of the reflowed mask pattern MK1 may be transferred to the preliminary lens layer MLL to form preliminary microlenses PML having a first curvature discussed with reference to FIG. 4B.

Referring to FIG. 11C, a second mask pattern MK2 may be formed to cover a central part PML_C of each of the preliminary microlenses PML and to expose an edge part PML_E of each of the preliminary microlenses PML. The second mask pattern MK2 may be a photoresist pattern formed by a photolithography process.

Referring to FIGS. 11C and 11D, the exposed edge parts PML_E of the preliminary microlenses PML on a side of the second mask pattern MK2 may be etched to form a lens edge part ML_E having a second curvature. The second mask pattern MK2 may be removed. Therefore, microlenses ML of FIG. 4B may be formed.

Still another method may be used to fabricate the image sensor 500 of FIG. 4A.

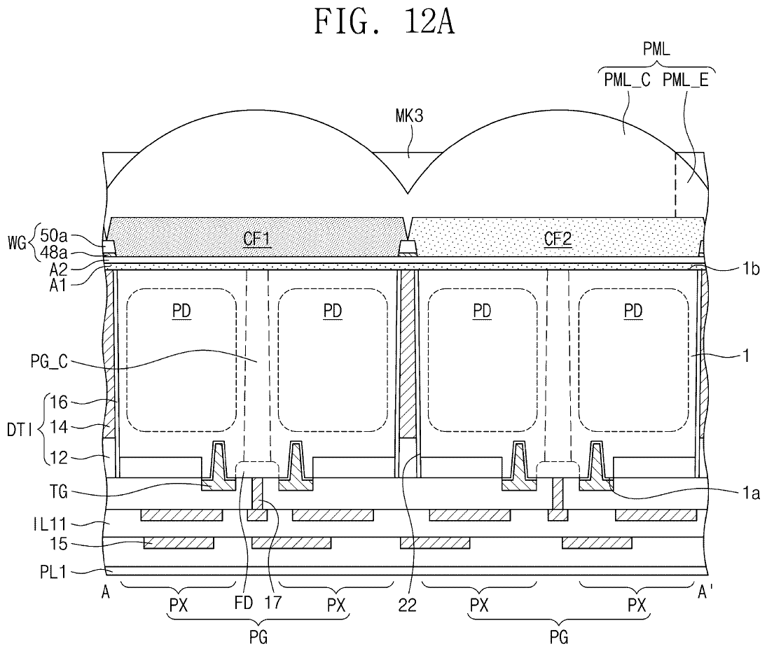

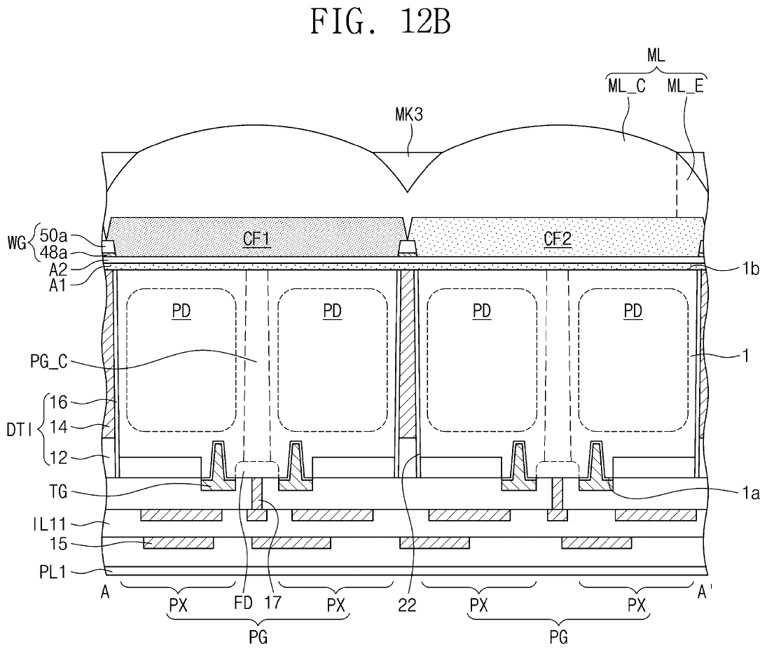

FIGS. 12A and 12B illustrate cross-sectional views showing a method of fabricating an image sensor having the cross-section of FIG. 4A.

Referring to FIG. 12A, the preliminary lens layer MLL may be etched by performing a blanket etch-back process in a state where the reflowed mask pattern MK1 of FIG. 11A is formed. Therefore, a profile of the reflowed mask pattern MK1 may be transferred to the preliminary lens layer MLL to form preliminary microlenses PML having a second curvature discussed with reference to FIG. 4B. A third mask pattern MK3 may be formed to cover edge parts PML_E of the preliminary microlenses PML and to expose central parts PML_C of the preliminary microlenses PML. The third mask pattern MK3 may be, for example, a spin on hardmask (SOH) or an amorphous carbon layer (ACL). The central parts PML_C of the preliminary microlenses PML may upwardly protrude from the third mask pattern MK3.

Referring to FIG. 12B, an etching process may be performed to partially remove the central parts PML_C of the preliminary microlenses PML that upwardly protrude from the third mask pattern MK3. Therefore, a lens central part ML_C may be formed which has a first curvature. The third mask pattern MK3 may be removed. Therefore, microlenses ML of FIG. 4B may be formed.

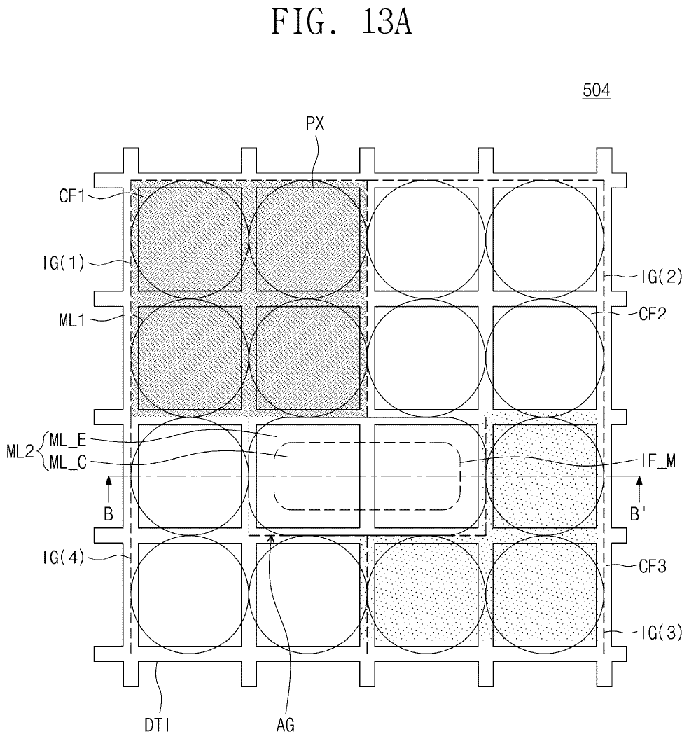

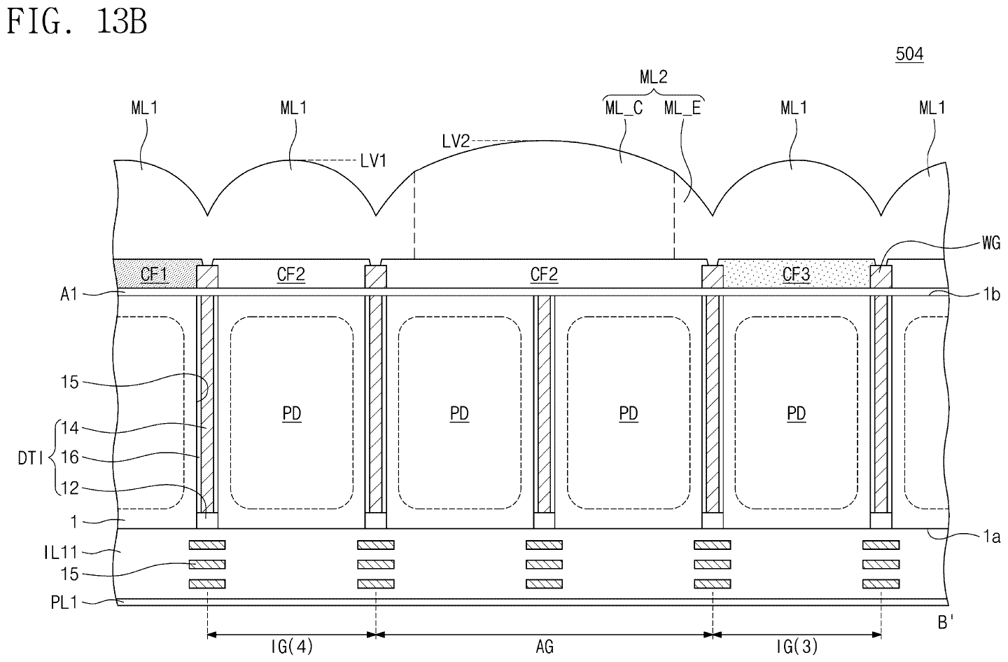

FIG. 13A illustrates a plan view showing an image sensor according to some embodiments of the present inventive concepts. FIG. 13B illustrates a cross-sectional view taken along line B-B′ of FIG. 13A.

Referring to FIGS. 13A and 13B, an image sensor 504 according to some embodiments may be configured such that the first substrate 1 is provided therein with the pixel separation structure DTI that separates a plurality of pixels PX from each other. The pixels PX may be two-dimensionally provided along the first direction X and the second direction Y. The pixels PX may constitute pixel groups IG and AG. The pixel groups IG and AG may include an image pixel group IG and an autofocus pixel group AG. The image pixel group IG may include first to fourth image pixel groups IG(1) to IG(4) that are disposed along a clockwise direction.

The first and second image pixel groups IG(1) and IG(2) may each include four pixels PX that are arranged in two columns and two rows adjacent to each other. The third and fourth image pixel groups IG(3) and IG(4) may each include three pixels PX adjacent to each other. The autofocus pixel group AG may include two pixels PX adjacent to each other. The first image pixel group IG(1) may be covered with a first color filter CF1. The third image pixel group IG(3) may be covered with a third color filter CF3. The second and third image pixel groups IG(2) and IG(4) and the autofocus pixel group AG may be covered with a second color filter CF2. The second color filter CF2 may be, for example, green. The first color filter CF1 and the third color filter CF3 may be red and blue, respectively.

On the image pixel group IG, first microlenses ML1 may be provided corresponding to the pixel PX. The first microlens ML1 may have a fourth curvature at a top surface thereof. The fourth curvature may be a continuous curvature. A second microlens ML2 may be provided on the autofocus pixel group AG. The second microlens ML2 may be analogous to the microlens ML discussed with reference to FIG. 4A. The second microlens ML2 may have a lens central part ML_C of a first curvature and a lens edge part ML_E of a second curvature. The second microlens ML2 may have a lens corner IF_M. The first microlens ML1 may have no lens corner. The first microlens ML1 may have a top end at a first level LV1, and the second microlens ML2 may have a top end at a second level LV2 higher than the first level LV1. Other configurations and/or components of the embodiments according to FIGS. 13A and 13B may be identical or similar to those discussed with reference to FIGS. 3A to 9.

FIG. 14 illustrates a cross-sectional view showing an image sensor according to some embodiments of the present inventive concepts.

Referring to FIG. 14, an image sensor 505 according to some embodiments may include a first substrate 1 having a pixel array area APS, an optical black area OB, and a pad area PR, and may also include a wiring layer 200 on a first surface 1a of the first substrate 1 and a base substrate 400 on the wiring layer 200. The wiring layer 200 may include an upper wiring layer 221 and a lower wiring layer 223. The pixel array area APS may include a plurality of pixels PX. The pixels PX arranged on the pixel array area APS may be substantially the same as those discussed above with reference to FIGS. 1 to 13B.

On the optical black area OB, the first substrate 1 may be provided thereon with a first connection structure 50, a connection contact 81, and a bulk color filter 90. The first connection structure 50 may include a first light-shield pattern 51, a dielectric pattern 53, and a first capping pattern 55.

The first light-shield pattern 51 may be on a second surface 1b of the first substrate 1. For example, the first light-shield pattern 51 may cover a second dielectric layer 136 on the second surface 1b, and may cover and conform to an inner wall of a third trench TR3 and an inner wall of a fourth trench TR4. The first light-shield pattern 51 may penetrate a photoelectric conversion layer 150 and the upper wiring layer 221, and may connect the photoelectric conversion layer 150 to the wiring layer 200. For example, the first light-shield pattern 51 may be in contact with interconnection lines in the upper and lower wiring layers 221 and 223 and with the separation conductive pattern 14 of the pixel separation structure DTI of FIG. 4A in the photoelectric conversion layer 150. Therefore, the first connection structure 50 may be electrically connected to interconnection lines in the wiring layer 200. The first light-shield pattern 51 may include a metallic material, such as tungsten. The first light-shield pattern 51 may block incidence of light into the optical black area OB.

The connection contact 81 may be provided in the third trench TR3 to fill an unoccupied portion of the third trench TR3.

The connection contact 81 may include a metallic material, such as aluminum. The connection contact 81 may be in contact with the separation conductive pattern 14 of the pixel separation structure DTI depicted in FIG. 4A. A negative bias voltage may be applied through the connection contact 81 to the separation conductive pattern 14. Therefore, it may be possible to prevent or reduce white spot and/or dark current.

The dielectric pattern 123 may fill an unoccupied portion of the fourth trench TR4. The dielectric pattern 123 may penetrate completely or partially the photoelectric conversion layer 150 and the wiring layer 200. The first capping pattern 55 may be provided on a top surface of the dielectric pattern 53. The first capping pattern 55 may be provided on the dielectric pattern 53.

The bulk color filter 90 may be provided on the connection contact 81, the first light-shield pattern 51, and the first capping pattern 55. The bulk color filter 90 may cover the connection contact 81, the first light-shield pattern 51, and the first capping pattern 55. A first protection layer 71 may be provided on and encapsulate the bulk color filter 90.

A photoelectric conversion element PD′ and a dummy element PD″ may be provided on the optical black area OB of the first substrate 1. The photoelectric conversion element PD′ may be, for example, doped with impurities having the second conductivity type different from the first conductivity type. The second conductivity type may be, for example, an n-type. The pixel array area APS may include a plurality of pixels PX. The photoelectric conversion element PD′ may have a similar structure to that of a photoelectric conversion element PD, but may not execute the same operation (e.g., generation of electrical signals from received light) as that of the photoelectric conversion element PD. The dummy element PD″ may not be doped with impurities. The dummy element PD″ may generate signals that are used as information to remove subsequent process noise.

On the pad area PR, the first substrate 1 may be provided thereon with a second connection structure 60, a second conductive pad 83, and a second protection layer 73. The second connection structure 60 may include a second light-shield pattern 61, a dielectric pattern 63, and a second capping pattern 65.

The second light-shield pattern 61 may be on the second surface 1b of the first substrate 1. For example, the second light-shield pattern 61 may cover the second dielectric layer 136 on the second surface 1b, and may cover and conform to an inner wall of a fifth trench TR5 and an inner wall of a sixth trench TR6. The second light-shield pattern 61 may penetrate the photoelectric conversion layer 150 and the upper wiring layer 221, and may connect the photoelectric conversion layer 150 to the wiring layer 200. For example, the second light-shield pattern 61 may be in contact with interconnection lines in the lower wiring layer 223. Therefore, the second connection structure 130 may be electrically connected to interconnection lines in the wiring layer 200. The second light-shield pattern 131 may include a metallic material, such as tungsten.

A second conductive pad 83 may be provided in the fifth trench TR5 to fill an unoccupied portion of the fifth trench TR5. The second conductive pad 83 may include a metallic material, such as aluminum. The second conductive pad 83 may serve as an electrical connection path through which an image sensor device is connected to an external apparatus. The dielectric pattern 63 may fill an unoccupied portion of the sixth trench TR6. The dielectric pattern 63 may penetrate completely or partially the photoelectric conversion layer 150 and the wiring layer 200. The second capping pattern 65 may be provided on the dielectric pattern 63. The second protection layer 73 may cover the second capping pattern 65 and a portion of the second light-shield pattern 61.

A current applied through the second conductive pad 83 may flow to the separation conductive pattern 14 of the pixel separation structure DTI by way of the second light-shield pattern 61, interconnection lines in the wiring layer 200, and the first light-shield pattern 51. The photoelectric conversion elements PD and PD′ and the dummy element PD″ may generate electrical signals, and the electrical signals may be outwardly transmitted through wiring lines in the wiring layer 200, the second light-shield pattern 131, and the second conductive pad 83.

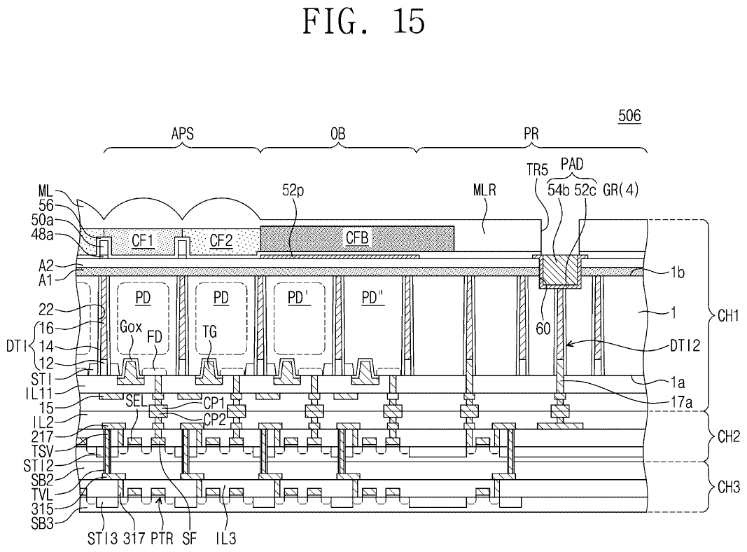

FIG. 15 illustrates a cross-sectional view showing an image sensor according to some embodiments of the present inventive concepts.

Referring to FIG. 15, an image sensor 506 according to some embodiments may have a structure in which first to third sub-chips CH1 to CH3 are sequentially bonded. The first sub-chip CH1 may have, for example, an image sensing function.

The first sub-chip CH1 may include transfer gates TG on a front surface 1a of a first substrate 1, and may also include first interlayer dielectric layers IL11 that cover the transfer gates TG. The first substrate 1 may be provided therein a first device separation part STI1 that defines active sections. The first sub-chip CH1 may further include inner connection contacts 17a. On a pad area PR, at least one of the inner connection contacts 17a may penetrate a buried dielectric pattern 12 of a pixel separation structure DTI to connect one of first wiring lines 15 to a separation conductive pattern 14 of the pixel separation structure DTI, thereby applying a negative bias voltage to the separation conductive pattern 14.

Microlenses ML may have their shapes the same as or similar to that discussed with reference to FIGS. 3A to 13B. A lens residual layer MLR may include the same material as that of the microlenses ML. On the pad area PR, the lens residual layer MLR may have an opening 35 that is formed to expose a backside conductive pad PAD.

The backside conductive pad PAD may be in a fifth trench TR5. The backside conductive pad PAD may include a second conductive pattern 52c and a second metal pattern 54b. The second conductive pattern 52c may cover and conform to lateral and bottom surfaces of the fifth trench TR5. The second conductive pattern 52c may have a single-layered or multi-layered structure of at least one selected from a titanium layer, a titanium nitride layer, and a tungsten layer. The second metal pattern 54b may include, for example, aluminum. The second metal pattern 54b may fill the fifth trench TR5.

At least another of the inner connection contacts 17a may penetrate a buried dielectric pattern 12 of a second pixel separation part DTI2 below the backside conductive pad PAD to connect one of the first wiring lines 15 to a separation conductive pattern 14 of the second pixel separation part DTI2. A first conductive pad CP1 may be in a lowermost first interlayer dielectric layer IL11. The first conductive pad CP1 may include copper. On the edge area ER, the lens residual layer MLR may be disposed on a second optical black pattern CFB.

The second sub-chip CH2 may include a second substrate SB2, selection gates SEL, source follower gates SF, and reset gates (not shown) that are on the second substrate SB2, and second interlayer dielectric layers IL2 that cover the selection gates SEL, the source follower gates SF, and the reset gates. The second substrate SB2 may be provided therein with a second device separation part STI2 that defines active sections. The second interlayer dielectric layers IL2 may be provided therein with second contacts 215 and second wiring lines 217. A second conductive pad CP2 may be in an uppermost second interlayer dielectric layer IL2. The second conductive pad CP2 may include copper. The second conductive pad CP2 may be in contact with the first conductive pad CP1. The source follower gates SF may be connected to corresponding floating diffusion regions FD of the first sub-chip CH1.

The third sub-chip CH3 may include a third substrate SB3, peripheral transistors PTR on the third substrate SB3, and third interlayer dielectric layers IL3 that cover the peripheral transistors PTR. The third substrate SB3 may be provided therein with a third device separation part STI3 that defines active sections. The third interlayer dielectric layers IL3 may be provided therein with third contacts 317 and third wiring lines 315. An uppermost third interlayer dielectric layer IL3 may be in contact with the second substrate SB2. A through electrode TSV may penetrate or extend through the second interlayer dielectric layer IL2, the second device separation part STI2, the second substrate SB2, and the third interlayer dielectric layer IL3 and may connect one of the second wiring lines 217 to one of the third wiring lines 315. A sidewall of the through electrode TSV may be surrounded with a via dielectric layer TVL. The third sub-chip CH3 may include circuits either for driving one or both of the first sub-chip CH1 and the second sub-chip CH2 or for storing electrical signals generated from one or both of the first sub-chip CH1 and the second sub-chip CH2.

A microlens included in an image sensor of the present inventive concepts may have a plurality of curvatures to improve light sensitivity and to increase autofocus contrast (AF-C). Accordingly, it may be possible to provide an autofocus image sensor producing clear images.

Although the present inventive concepts have been described in connection with some examples of embodiments thereof that are illustrated in the accompanying drawings, it will be understood to those skilled in the art that various changes and modifications may be made without departing from the technical spirit and essential feature of the present inventive concepts. For example, unless mutually exclusive and/or explicitly described herein to be incompatible, embodiments and aspects of embodiments described variously with respect to FIGS. 1 to 15 may be combined with each other, and such combinations are considered within the technical spirit and essential feature of the present inventive concepts. It will also be apparent to those skilled in the art that various substitution, modifications, and changes may be thereto without departing from the scope and spirit of the present inventive concepts.

1. An image sensor, comprising:
a first substrate having a first surface and a second surface that are opposite to each other;
a plurality of pixels provided in the first substrate and arranged in a plurality of pixel groups, wherein each of the pixel groups includes four pixels arranged in two columns and two rows;
a pixel separation structure provided in the first substrate, wherein the pixel separation structure includes a pixel group separation part that separates each pixel group from adjacent pixel groups and a pixel separation part that separates the pixels in each pixel group from each other; and
a plurality of microlenses on the first surface, wherein the plurality of microlenses respectively overlap the plurality of pixel groups,
wherein each of the microlenses includes a central part that has a first curvature and an edge part that has a second curvature, and
wherein the first curvature is less than the second curvature.

2. The image sensor of claim 1, wherein a lens corner is defined between the central part and the edge part.

3. The image sensor of claim 1, wherein
the central part has a first curvature radius, and
the edge part has a second curvature radius that is less than the first curvature radius.

4. The image sensor of claim 3, wherein the first curvature radius is equal to or greater than about 1.5 times the second curvature radius.

5. The image sensor of claim 1, wherein
the central part has a first focal distance, and
the edge part has a second focal distance that is less than the first focal distance.

6. The image sensor of claim 1, wherein a second focus of the edge part is at a point between about −500 nanometers (nm) to about +500 nm from the first surface toward the second surface.

7. The image sensor of claim 1, wherein each of the microlenses further includes a connection part that is between the central part and the edge part, the connection part having a third curvature,
wherein the third curvature is greater than the first curvature and less than the second curvature.

8. The image sensor of claim 1, further comprising a protection layer that covers the microlenses,
wherein the protection layer includes a first part on the central part of each microlens and a second part on the edge part of each microlens, and
wherein a curvature of the first part is less than a curvature of the second part.

9. An image sensor, comprising:
a first substrate having a first surface and a second surface that are opposite to each other;
a plurality of pixels provided in the first substrate and arranged into a plurality of pixel groups, each of the pixel groups including pixels arranged in m columns and n rows, where at least one of m and n is a natural number equal to or greater than 2;
a pixel separation structure provided in the first substrate, wherein the pixel separation structure includes a pixel group separation part that separates each pixel group from adjacent pixel groups and a pixel separation part that separates the pixels in each pixel group from each other; and
a plurality of microlenses on the first surface, wherein the plurality of microlenses respectively overlap the plurality of pixel groups,
wherein each of the microlenses includes a central part that has a first curvature radius and an edge part that has a second curvature radius, and
wherein the first curvature radius is greater than the second curvature radius.

10. The image sensor of claim 9, wherein a lens corner providing a discontinuity is between the central part and the edge part.

11. The image sensor of claim 9, wherein the first curvature radius is equal to or greater than about 1.5 times the second curvature radius.

12. The image sensor of claim 9, further comprising:
the central part has a first focal distance, and
the edge part has a second focal distance that is less than the first focal distance.

13. The image sensor of claim 9, wherein a second focus of the edge part is at a point about −500 nm to about +500 nm from the first surface toward the second surface.

14. The image sensor of claim 9, wherein each of the microlenses further include a connection part that is between the central part and the edge part, the connection part having a third curvature radius,
wherein the third curvature radius is less than about first curvature radius and is greater than the second curvature radius.

15. The image sensor of claim 9, further comprising a protection layer that covers the plurality of microlenses,
wherein the protection layer includes a first part on the central part of each microlens and a second part on the edge part of each microlens, and
wherein a curvature of the first part is less than a curvature of the second part.

16. An image sensor, comprising:
a first substrate having a first surface and a second surface that are opposite to each other;
a plurality of pixels provided in the first substrate and arranged into a plurality of pixel groups, each of the pixel groups including four pixels arranged in two columns and two rows;
a photoelectric conversion element in the first substrate in each of the pixels;
a transfer gate on the second surface for each of the pixels;
a pixel separation structure on the first surface, wherein the pixel separation structure includes a polysilicon pattern and a dielectric pattern that surrounds a lateral surface of the polysilicon pattern, the pixel separation structure including a pixel group separation part that separates each pixel group from adjacent pixel groups and a pixel separation part that separates the pixels in each pixel group from each other;
a plurality of color filters on the first surface, the plurality of color filters respectively overlapping the plurality of pixel groups; and
a plurality of microlenses correspondingly on the color filters,
wherein each of the microlenses includes a central part that has a first curvature and an edge part that has a second curvature,
wherein the central part has a first focal distance,
wherein the edge part has a second focal distance less than the first focal distance, and
wherein a second focus of the edge part is at a point about −500 nanometers (nm) to about +500 nm from the first surface toward the second surface.

17. The image sensor of claim 16, wherein a lens corner provided is between the central part and the edge part.

18. The image sensor of claim 16, wherein:
the central part has a first curvature radius,
the edge part has a second curvature radius, and
the first curvature radius is equal to or greater than about 1.5 times the second curvature radius.

19. The image sensor of claim 16, wherein each of the microlenses further include a connection part that is between the central part and the edge part, the connection part having a third focal distance,
wherein the third focal distance is less than the first focal distance and greater than the second focal distance.

20. The image sensor of claim 16, further comprising a protection layer that covers the microlenses,
wherein the protection layer includes a first part on the central part of each microlens and a second part on the edge part of each microlens, and
wherein a curvature of the first part is less than a curvature of the second part.

21-22. (canceled)
